(19) United States
(12) Patent Application Publication
(10) Pub. No.: US 2024/0355968 A1
(43) Pub. Date: Oct. 24, 2024

(54) LIGHT EMITTING ELEMENT AND LIGHT EMITTING DEVICE

(71) Applicant: TOYODA GOSEI CO., LTD., Kiyosu-shi (JP)

(72) Inventor: Koichi GOSHONOO, Kiyosu-shi (JP)

(21) Appl. No.: 18/631,818

(22) Filed: Apr. 10, 2024

(30) Foreign Application Priority Data
Apr. 19, 2023 (JP) 2023-068771

(51) Int. Cl. H01L 33/32; H01L 27/15; H01L 33/50; H01L 33/58; H01L 33/62

(52) U.S. Cl. CPC H01L 33/32; H01L 27/156; H01L 33/507; H01L 33/58; H01L 33/62

(57) ABSTRACT

A flip-chip type light emitting element includes: an n-layer made containing a group III nitride semiconductor; an active layer containing a group III nitride semiconductor provided over the n-layer; a p-layer containing a group III nitride semiconductor provided over the active layer; a groove provided at a partial region of the p-layer and having a depth reaching the n-layer; an n-electrode provided over the n-layer exposed at a bottom surface of the groove; a p-electrode provided over the p-layer; and a conductive film provided at a surface of the n-layer opposite to a side in which the active layer is provided and having a region through which light from the active layer is transmitted.

### CROSS-REFERENCE TO RELATED APPLICATION

This application is based on and claims priority under 35 USC 119 from Japanese Patent Application No. 2023-068771 filed on Apr. 19, 2023.

### TECHNICAL FIELD

The present invention relates to a light emitting element and a light emitting device.

### BACKGROUND ART

In recent years, higher definition of displays has been required, and a micro LED display has attracted attention. A micro LED display is a display in which minute LEDs on an order of 1 μm to 100 μm are arranged in a matrix, and the minute LEDs are used as one sub-pixel. As the micro LED display, a structure in which a micro LED is an individual chip and a monolithic structure in which a plurality of micro LEDs are fabricated on one chip are known. JP2021-158179A describes such a monolithic micro LED.

### SUMMARY OF INVENTION

In the monolithic micro LED, it is conceivable to provide an n-electrode in an outer peripheral portion of an element in order to densely arrange sub-pixels. In this case, a sub-pixel at a central portion of the element is farther from the n-electrode than a sub-pixel at an end portion of the element.

However, in the case of such a monolithic micro LED, a voltage required for driving the sub-pixel at the central portion becomes higher than a voltage required for driving the sub-pixel at the end portion. This is because a current flows through an n-layer from the pixel at the central portion to the n-electrode in the outer peripheral portion, and a voltage drop corresponding to a sheet resistance of the n-layer occurs.

In the monolithic micro LED, there is a demand to reduce a thickness of the n-layer. This is to prevent warpage of a substrate. This is also to prevent diffusion of light in the n-layer and prevent mixing of light between adjacent sub-pixels.

However, when the thickness of the n-layer is reduced, the sheet resistance of the n-layer increases, and the voltage required for driving the sub-pixel at the central portion increases.

The present invention has been made in view of such a background, and an object of the present invention is to provide a light emitting element in which a voltage required for driving a region away from an n-electrode is reduced.

An aspect of the invention is directed to a flip-chip type light emitting element including:
an n-layer made containing a group III nitride semiconductor;
an active layer containing a group III nitride semiconductor provided over the n-layer;
a p-layer containing a group III nitride semiconductor provided over the active layer;
a groove provided at a partial region of the p-layer and having a depth reaching the n-layer;
an n-electrode provided over the n-layer exposed at a bottom surface of the groove;
a p-electrode provided over the p-layer; and
a conductive film provided at a surface of the n-layer opposite to a side in which the active layer is provided and having a region through which light from the active layer is transmitted.

According to the above aspect, the sheet resistance of the n-layer can be substantially reduced by providing the conductive film in the n-layer. As a result, the voltage required for driving the region away from the n-electrode can be reduced.

### BRIEF DESCRIPTION OF DRAWINGS

FIG. 1 is a cross-sectional view showing a configuration of a light emitting device according to a first embodiment, and is a cross section perpendicular to a main surface of the light emitting device.

FIG. 2 is a plan view of a monolithic micro LED as viewed from an electrode side.

FIG. 3 is a diagram showing a manufacturing process of the light emitting device according to the first embodiment.

FIG. 4 is a diagram showing the manufacturing process of the light emitting device according to the first embodiment.

FIG. 5 is a diagram showing the manufacturing process of the light emitting device according to the first embodiment.

FIG. 6 is a diagram showing the manufacturing process of the light emitting device according to the first embodiment.

FIG. 7 is a diagram showing the manufacturing process of the light emitting device according to the first embodiment.

FIG. 8 is a diagram showing the manufacturing process of the light emitting device according to the first embodiment.

FIG. 9 is a diagram showing the manufacturing process of the light emitting device according to the first embodiment.

FIG. 10 is a diagram showing the manufacturing process of the light emitting device according to the first embodiment.

FIG. 11 is a diagram showing the manufacturing process of the light emitting device according to the first embodiment.

FIG. 12 is a cross-sectional view showing a configuration of a light emitting device according to a second embodiment, and is a cross section perpendicular to a main surface of the light emitting device.

FIG. 13 is a cross-sectional view showing a configuration of a light emitting device according to a third embodiment, and is a cross section perpendicular to a main surface of the light emitting device.

FIG. 14 is a cross-sectional view showing a configuration of a light emitting device according to a fourth embodiment, and is a cross section perpendicular to a main surface of the light emitting device.

FIG. 15 is a graph showing a transmission spectrum of a filter.

FIG. 16 is a graph showing a spectrum of red light from a third active layer.

FIG. 17 is a chromaticity diagram showing a color gamut of a monolithic micro LED.

### DETAILED DESCRIPTION OF THE INVENTION

A light emitting element is of a flip-chip type. The light emitting element includes an n-layer made of a group III nitride semiconductor, an active layer made of a group III nitride semiconductor provided on the n-layer, a p-layer made of a group III nitride semiconductor provided on the active layer, a groove provided in a partial region of the p-layer and having a depth reaching the n-layer, an n-electrode provided on the n-layer exposed at a bottom surface of the groove, a p-electrode provided on the p-layer, and a conductive film provided on a surface of the n-layer opposite to the active layer side and having a region through which light from the active layer is transmitted.

A filter formed of a dielectric multilayer film may be provided on the conductive film. A transmission spectrum of the filter may have a transmission band in a band including λ and a stop band on a shorter wavelength side than 2, where a peak of an emission wavelength of the active layer is λ, and the stop band may overlap with the emission spectrum of the active layer.

The light emitting element may be a monolithic micro LED in which sub-pixels that emit light individually are two-dimensionally arranged.

The conductive film may be made of a transparent conductive material.

A microlens may be provided at a position where the microlens faces each sub-pixel, on a surface of the n-layer on the conductive film side. The conductive film may be provided in a region excluding the microlens on the surface of the n-layer on the conductive film side, and the conductive film may be made of a material that does not transmit light from the active layer.

A total film thickness from the n-layer to the p-layer may be three times or less a width of the sub-pixel. A total film thickness from the n-layer to the p-layer may be twice or less a width of the sub-pixel.

A light emitting device includes the light emitting element described above, and a backplane connected to the n-electrode and the p-electrode of the light emitting element and including a drive circuit that individually drives the sub-pixels of the light emitting element.

The backplane may include a back electrode connected to the drive circuit on a surface opposite to a LED side.

An outer periphery of the light emitting element and an outer periphery of the backplane may coincide with each other in a plan view.

### First Embodiment

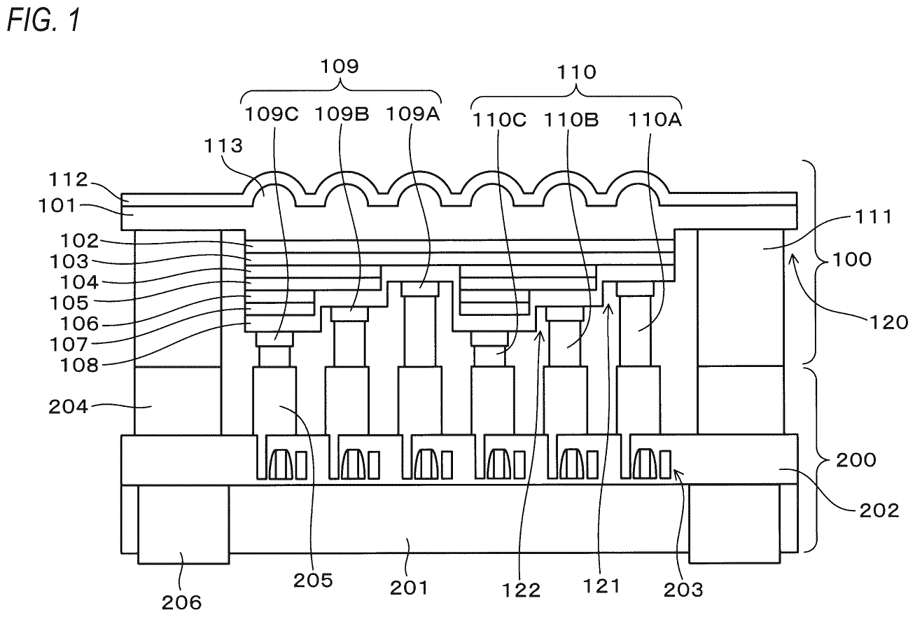

FIG. 1 is a cross-sectional view showing a configuration of a light emitting device according to a first embodiment, and is a cross-sectional view taken in a direction perpendicular to a main surface of a substrate. The light emitting device according to the first embodiment includes a monolithic micro LED 100 and a backplane 200 for driving the LED 100.

The monolithic micro LED 100 is a one-chip element in which light emitting elements emitting blue, green, and red light are two-dimensionally arranged, and is a flip-chip type. Each light emitting element is one sub-pixel of a display.

The backplane 200 is a substrate which is connected to the monolithic micro LED 100 and on which a drive circuit for driving the monolithic micro LED 100 is formed. As shown in FIG. 1, the monolithic micro LED 100 is flip-chip mounted on the backplane 200. With such a configuration, wiring between the monolithic micro LED 100 and the drive circuit is not required, and problems such as voltage drop and reliability in the wiring due to miniaturization and high definition of the monolithic micro LED 100 do not occur.

### 1. Configuration of Monolithic Micro LED 100

As shown in FIG. 1, the monolithic micro LED 100 includes a layer in which an n-layer 101, a first active layer 102, a first intermediate layer 103, a second active layer 104, a second intermediate layer 105, a third active layer 106, and a protective layer 107 are stacked in this order, a p-layer 108 as a regrowth layer, a p-contact electrode 109, a p-electrode 110, an n-electrode 111, and a conductive film 112.

The n-layer 101 is an n-type group III nitride semiconductor. Examples thereof include n-GaN, n-AlGaN, and n-InGaN. A concentration of Si is, for example, 1×10¹⁸ cm⁻³ to 100×10¹⁸ cm⁻³.

A thickness of the n-layer 101 is preferably 3 μm or less. This is to reduce the warpage of the monolithic micro LED 100. The thickness of the n-layer 101 is more preferably 1 μm or less. The thickness of the n-layer 101 is preferably 0.5 μm or more.

The first active layer 102 is provided on a surface of the n-layer 101 opposite to a light extraction side (surface opposite to a side on which a microlens 113 is provided). The first active layer 102 is a light emitting layer of SQW or MQW structure. An emission wavelength is blue, and is 440 nm to 480 nm. The first active layer 102 has a structure in which one to nine pairs of barrier layers made of AlGaN and well layers made of InGaN are alternately stacked. The number of pairs is more preferably 1 to 7, and further preferably 1 to 5.

An ESD layer or a base layer may be provided between the n-layer 101 and the first active layer 102 as necessary. The ESD layer is a layer provided to improve an electrostatic withstand voltage. For example, GaN, InGaN or AlGaN undoped or lightly doped with Si is used.

The base layer is a semiconductor layer having a superlattice structure, and is a layer for alleviating lattice strain of the semiconductor layer. For example, group III nitride semiconductor thin films (for example, two of GaN, InGaN, and AlGaN) having different compositions are alternately stacked, and the number of pairs is, for example, 3 to 30. The base layer may be undoped, or may be doped with Si at about 1×10¹⁷ cm⁻³ to 100×10¹⁷ cm⁻³. In addition, a superlattice structure may not be used as long as the strain can be alleviated. Any material may be used as long as it has a small difference in lattice constant at a heterointerface with the first active layer 102, and may be, for example, an InGaN-layer, an AlInN-layer, or an AlGaInN-layer.

The first intermediate layer 103 is provided on a surface of the first active layer 102 opposite to the n-layer 101 side. The first intermediate layer 103 is a layer provided to enable light emission from the first active layer 102 and light emission from the second active layer 104 to be individually controlled. In addition, the first intermediate layer 103 also serves to protect the first active layer 102 from etching damage when a groove 121 to be described later is formed.

A material of the first intermediate layer 103 is GaN or InGaN. The first intermediate layer 103 may be non-doped or n-type. A plurality of layers having different In compositions may be used, or two layers of a non-doped layer and an n-layer may be used.

The second active layer 104 is provided on a surface of the first intermediate layer 103 opposite to the n-layer 101 side. The second active layer 104 is a light emitting layer of SQW or MQW structure. An emission wavelength is green and is 520 nm to 550 nm. The second active layer 104 has a structure in which one to seven pairs of barrier layers made of AlGaN and well layers made of InGaN are alternately stacked. The number of pairs is more preferably 1 to 5, and further preferably 1 to 3. The number of pairs is preferably equal to or less than the number of pairs of the first active layer 102, and more preferably less than the number of pairs of the first active layer 102.

The second intermediate layer 105 is provided on a surface of the second active layer 104 opposite to the n-layer 101 side. The second intermediate layer 105 is provided for the same reason as that of the first intermediate layer 103, and is a layer provided to enable light emission from the second active layer 104 and light emission from the third active layer 106 to be individually controlled. In addition, the second active layer 104 also serves to protect the second active layer 104 from etching damage when a groove 122 to be described later is formed. A material of the second intermediate layer 105 is similar to that of the first intermediate layer 103, and may be the same material.

The third active layer 106 is provided on a surface of the second intermediate layer 105 opposite to the n-layer 101 side. The third active layer 106 is a light emitting layer of SQW or MQW structure. An emission wavelength is red and is 600 nm to 630 nm. The third active layer 106 has a structure in which one to seven pairs of barrier layers made of AlGaN and well layers made of InGaN are alternately stacked. The number of pairs is more preferably 1 to 5, and further preferably 1 to 3. The number of pairs is preferably equal to or less than the number of pairs of the second active layer 104, and more preferably less than the number of pairs of the second active layer 104.

The protective layer 107 is provided on a surface of the third active layer 106 opposite to the n-layer 101 side. The protective layer 107 is a layer that protects the active layer and also functions as an electron blocking layer. The protective layer 107 may be made of a material having a wider band gap than the well layer of the third active layer 106, such as AlGaN, GaN or InGaN. A thickness of the protective layer 107 is preferably 2.5 nm to 50 nm, more preferably 5 nm to 25 nm. The protective layer 107 may be doped with impurities or Mg. In this case, a concentration of Mg is preferably 1×10¹⁸ cm⁻³ to 1000×10¹⁸ cm⁻³.

A partial region of the protective layer 107 is etched, and a groove 120 reaching the n-layer 101 from the protective layer 107, the groove 121 reaching the first intermediate layer 103 from the protective layer 107, and the groove 122 reaching the second intermediate layer 105 from the protective layer 107 are provided.

The p-layer 108 is continuously provided on a surface of the protective layer 107 opposite to the n-layer 101 side, the surface of the second intermediate layer 105 exposed in the groove 122, and the surface of the first intermediate layer 103 exposed in the groove 121. The p-layer 108 is p-GaN or p-InGaN. A concentration of Mg is, for example, 1×10¹⁹ cm⁻³ to 1×10²¹ cm⁻³. The p-layer 108 may include a plurality of layers having different In compositions or concentrations of Mg.

An electron blocking layer may be provided between the p-layer 108 and the protective layer 107, between the p-layer 108 and the second intermediate layer 105 exposed in the groove 122, and between the p-layer 108 and the first intermediate layer 103 exposed in the groove 121. The electron blocking layer is a layer that blocks electrons injected from the n-layer 101 to be efficiently confined in the first active layer 102, the second active layer 104, and the third active layer 106. The electron blocking layer may be a single layer of GaN or AlGaN, a structure in which two or more of AlGaN, GaN, and InGaN are stacked, or a structure in which they are stacked with only a composition ratio changed. Alternatively, a superlattice structure may be employed. A thickness of the electron blocking layer is preferably 5 nm to 50 nm, more preferably 5 nm to 25 nm. A concentration of Mg of the electron blocking layer is preferably 1×10¹⁹ cm⁻³ to 100×10¹⁹ cm⁻³.

The p-contact electrode 109 is provided separately in a region facing the protective layer 107, a region facing the second intermediate layer 105 exposed in the groove 122, and a region facing the first intermediate layer 103 exposed in the groove 121, on a surface of the p-layer 108 opposite to the n-layer 101 side. A material of the p-contact electrode 109 is a material having a low contact resistance with respect to the p-layer 108, and examples thereof include Ag, Ni/Au, Co/Au, ITO/Ni/Al, Rh, Ru, ITO, and IZO. Hereinafter, in the p-contact electrode 109, a portion provided in the region facing the first intermediate layer 103 exposed in the groove 121 is referred to as a p-contact electrode 109A, a portion provided in the region facing the second intermediate layer 105 exposed in the groove 122 is referred to as a p-contact electrode 109B, and a portion provided in the region facing the protective layer 107 is referred to as a p-contact electrode 109C.

The p-electrode 110 is separately provided on surfaces of the p-contact electrodes 109A to 109C on an opposite side to the n-layer 101 side. Hereinafter, a portion of the p-electrode 110 provided on the p-contact electrode 109A is referred to as a p-electrode 110A, a portion thereof provided on the p-contact electrode 109B is referred to as a p-electrode 110B, and a portion thereof provided on the p-contact electrode 109C is referred to as a p-electrode 110C. The p-electrode 110 is an electrode bonded to the backplane 200 side. A material of the p-electrode 110 is, for example, Ti/Au, and can be the same material as the n-electrode 111.

The n-electrode 111 is provided on a surface of the n-layer 101 exposed by the groove 120. The n-electrode 111 is an electrode that makes contact with the n-layer 101 and is bonded to the backplane 200 side. A material of the n-electrode 111 is, for example, Ti/Au.

The microlens 113 is provided on a surface of the n-layer 101 on the light extraction side (a surface opposite to the first active layer 102 side). The microlens 113 is provided by roughening the surface of the n-layer 101, and has a hemispherical shape. The microlens 113 is provided at a position where the microlens 113 faces the p-contact electrode 109 in a plan view. Thus, the microlens 113 is provided for each sub-pixel. A diameter of the microlens 113 is approximately the same as the diameter of a circumscribed circle of the p-contact electrode 109. For example, the diameter of the microlens 113 is 0.8 times to 1.2 times the diameter of the circumscribed circle of the p-contact electrode 109. The microlens 113 is used to narrow the light from each sub-pixel and increase the contrast of the display.

A thickness of the semiconductor layer (a total film thickness of the n-layer 101 to the p-layer 108, that is, a total thickness of the n-layer 101, the first active layer 102, the first intermediate layer 103, the second active layer 104, the second intermediate layer 105, the third active layer 106, the protective layer 107, and the p-layer 108) is preferably three times or less the width of the sub-pixel. Here, a width of the sub-pixel is a diameter of a circumscribed circle of the sub-pixel. When the thickness of the semiconductor layer is three times or less the width of the sub-pixel, a coupling efficiency between the light from the sub-pixel and the corresponding microlens 113 is increased, and a light extraction efficiency and a light utilization rate can be increased. More preferably, the thickness of the semiconductor layer is twice or less the width of the sub-pixel.

The conductive film 112 is provided continuously on the surface on the light extraction side (the side opposite to the first active layer 102 side) of the surface of the n-layer 101 and the surface of the microlens. A material of the conductive film 112 may be a transparent conductive material, such as ITO, IZO, Nb, or Ta-doped TiO2. The conductive film 112 is provided to reduce the substantial sheet resistance of the n-layer 101. A thickness of the conductive film 112 may be sufficient as long as it can sufficiently reduce the substantial sheet resistance of the n-layer 101. For example, the thickness may be set such that the sheet resistance of the stacked layer of the n-layer 101 and the conductive film 112 is 30 2/a or less.

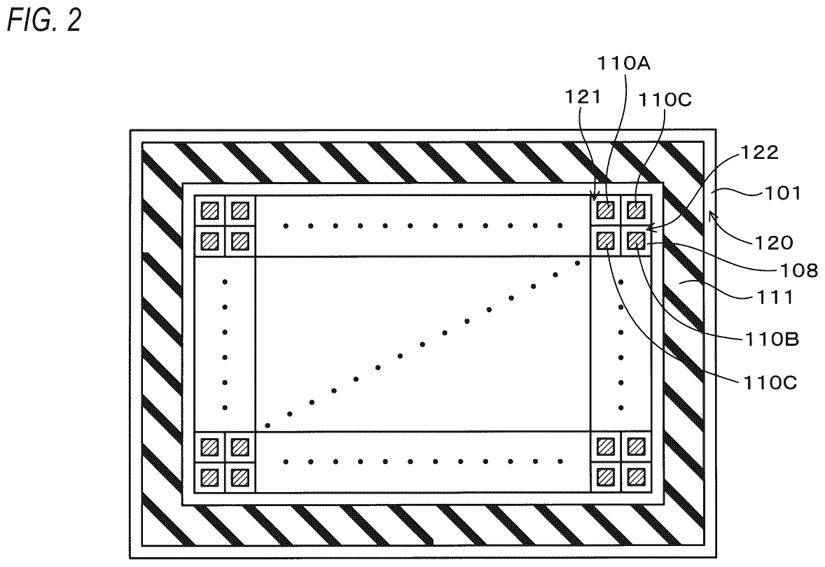

FIG. 2 is a plan view of the monolithic micro LED 100 as viewed from the side opposite to the light extraction side. As shown in FIG. 2, the monolithic micro LED 100 has a rectangular shape, and a rectangular ring-shaped groove 120 is provided in an outer peripheral portion thereof. The n-electrode 111 is provided in a rectangular ring shape inside the groove 120. In addition, inside the groove 120, pixels are arranged in a grid pattern, with each pixel consisting of four sub-pixels arranged in a 2×2 pattern.

As shown in FIG. 2, the 2×2 sub-pixels has a pattern in which the groove 121 and the groove 122 are diagonal to each other, and a region where the p-electrode 110A is provided in an upper portion of the groove 121 is a blue sub-pixel, a region where the p-electrode 110B is provided in an upper portion of the groove 122 is a green sub-pixel, and a region where the other two diagonal p-electrodes 110C are provided is a red sub-pixel. Normally, since red light emission is weaker than blue and green light, the number of red sub-pixels is increased by one.

As can be seen from FIG. 2, since the n-electrode 111 is provided in the outer peripheral portion, a distance from the n-electrode 111 to each sub-pixel is not uniform, and a sub-pixel at a central portion of the element has a longer distance to the n-electrode 111 than a sub-pixel at an end portion of the element. When driving the sub-pixel, a current flows approximately vertically from the p-electrode 110 to the p-layer 108 and from the p-layer 108 to the n-layer 101, and then the current flows horizontally through the n-layer 101 and reaches the n-electrode 111. Therefore, when the sub-pixel at the central portion of the element is driven, the voltage drop due to the sheet resistance of the n-layer 101 becomes large.

In the first embodiment, a growth substrate is removed from the n-layer 101, and the conductive film 112 is provided on the removed surface to reduce the substantial sheet resistance of the n-layer 101. That is, since most of the current flows horizontally through the conductive film 112 instead of through the n-layer 101, the sheet resistance is reduced. As a result, it is possible to reduce the voltage required for driving the sub-pixel at the central portion of the element. Since the substantial sheet resistance of the n-layer 101 can be reduced by the conductive film 112, the n-layer 101 can be thinned. Conventionally, in order to reduce the sheet resistance of the n-layer 101, it is necessary to increase the thickness of the n-layer 101 to some extent, and as a result, the warpage of the wafer is increased. In addition, since the n-layer 101 is thick, color mixing tends to occur between the sub-pixels. In the first embodiment, since the n-layer 101 can be thinned, the warpage of the n-layer 101 can be reduced. In addition, the color mixing between the sub-pixels is less likely to occur. For example, the thickness of the n-layer 101 may be about 1 μm.

The pattern of the n-electrode 111 and the pattern of the sub-pixel are not limited to those shown in FIG. 2. However, in order to realize a high-definition display with dense pixels, it is preferable to provide the n-electrode 111 in a ring shape on the outer peripheral portion as shown in FIG. 2.

### 2. Configuration of Backplane 200

The backplane 200 is an LSI for driving the monolithic micro LED 100, and as shown in FIG. 1, includes a substrate 201, an insulating film 202, transistors 203, an n-side bonding electrode 204, p-side bonding electrodes 205, and a back electrode 206.

The substrate 201 is made of Si. A plurality of transistors 203 are formed on one surface of the substrate 201. The number of transistors 203 is the same as the sub-pixels of the monolithic micro LED 100. The transistor 203 is provided at a position where the transistor 203 faces each sub-pixel of the monolithic micro LED 100 in a plan view. Light emission of each sub-pixel of the monolithic micro LED 100 is controlled by the transistor 203.

The insulating film 202 covers the substrate 201 and seals the transistor 203. The p-side bonding electrodes 205 is provided on the insulating film 202 in a region corresponding to an upper portion of each transistor 203, and the n-side bonding electrode 204 is provided on the insulating film 202 in an outer peripheral region. The p-side bonding electrode 205 is connected to a drain of the transistor 203 via a hole formed in the insulating film 202. In addition, the p-side bonding electrode 205 is bonded to the p-electrode 110 of the monolithic micro LED 100, and the n-side bonding electrode 204 is bonded to the n-electrode 111 of the monolithic micro LED 100.

The back electrode 206 connected to the outside is provided on the other surface of the substrate 201. The back electrode 206 is for inputting display control signals and power, and is connected to the n-side bonding electrode 204 and a gate and a source of the transistor 203 via a circuit including a transistor (not shown). A side surface of the back electrode 206 is covered with an insulating film, and is insulated from the substrate 201.

In a plan view, an outer periphery of the monolithic micro LED 100 and an outer periphery of the backplane 200 coincide with each other. That is, in a plan view, the monolithic micro LED 100 and the backplane 200 have the same rectangular shape. Further, in a plan view, a short side of the backplane 200 and a short side of the monolithic micro LED 100 coincide with each other, and a long side of the backplane 200 and a long side of the monolithic micro LED 100 coincide with each other. This is because the monolithic micro LED 100 and the backplane 200 are divided into elements after wafer bonding, as will be described later in a manufacturing method.

As described above, the light emitting device according to the first embodiment has a configuration in which the monolithic micro LED 100 and the backplane 200 as a drive circuit thereof are integrated into one chip by flip-chip mounting. By making the display into a single chip, it is possible to make the display smaller and more precise, and by reducing the number of wiring, it is possible to reduce a driving voltage and improve reliability.

Since the electrode (back electrode 206) connected to the outside is provided on a back surface side (the surface opposite to the monolithic micro LED 100 side) of the backplane 200, the outer peripheries of the monolithic micro LED 100 and the backplane 200 can be made to coincide with each other in a plan view, and the size of the entire light emitting device according to the first embodiment becomes substantially the same as the size of the monolithic micro LED 100, so that the light emitting device can be downsized.

### 3. Manufacturing Method for Light Emitting Device

Next, a manufacturing method for the light emitting device according to the first embodiment will be described with reference to the drawings.

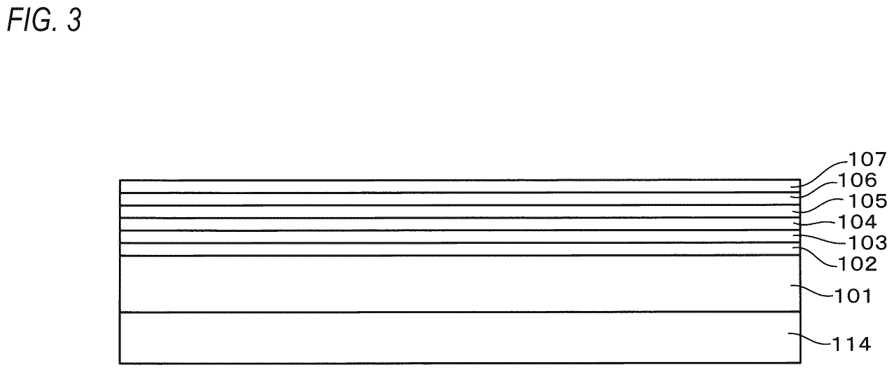

First, as shown in FIG. 3, the n-layer 101, the first active layer 102, the first intermediate layer 103, the second active layer 104, the second intermediate layer 105, the third active layer 106, and the protective layer 107 are sequentially stacked on a substrate 114 made of sapphire by MOCVD. A material of the substrate 114 is not limited to sapphire, and any material capable of growing a Group III nitride semiconductor may be used. For example, Si, GaN, ScAlMgO₄, or the like can be used.

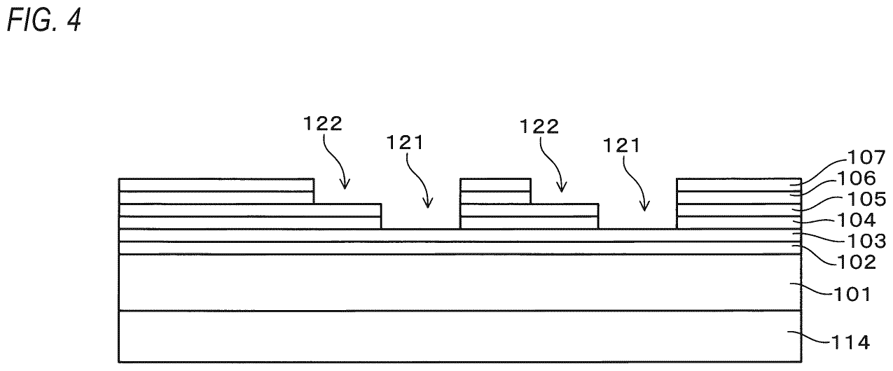

Next, as shown in FIG. 4, the grooves 121 and 122 are formed by dry etching a partial region of the protective layer 107. The groove 121 is etched until the first intermediate layer 103 is exposed, and the groove 122 is etched until the second intermediate layer 105 is exposed.

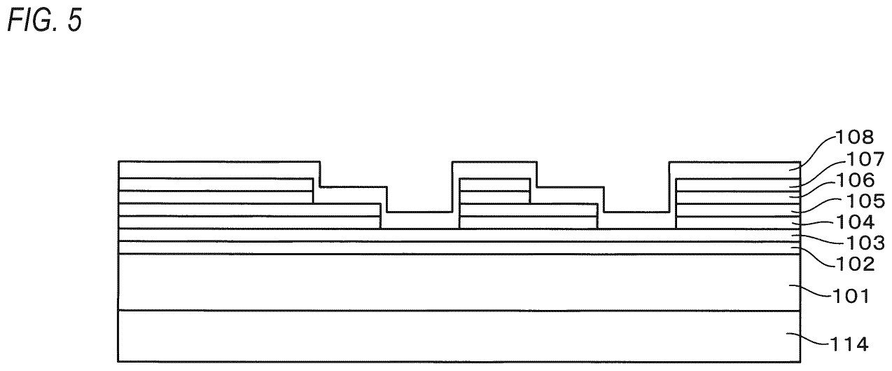

Next, as shown in FIG. 5, the p-layer 108 is formed continuously on a surface of the protective layer 107, a bottom surface of the groove 121, and a bottom surface of the groove 122 by MOCVD.

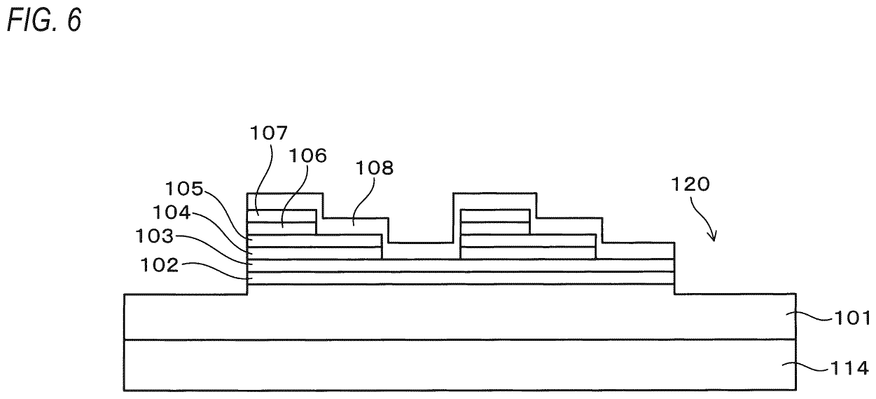

Next, as shown in FIG. 6, a predetermined region of the p-layer 108 is dry-etched to form the groove 120. The groove 120 is etched until the n-layer 101 is exposed.

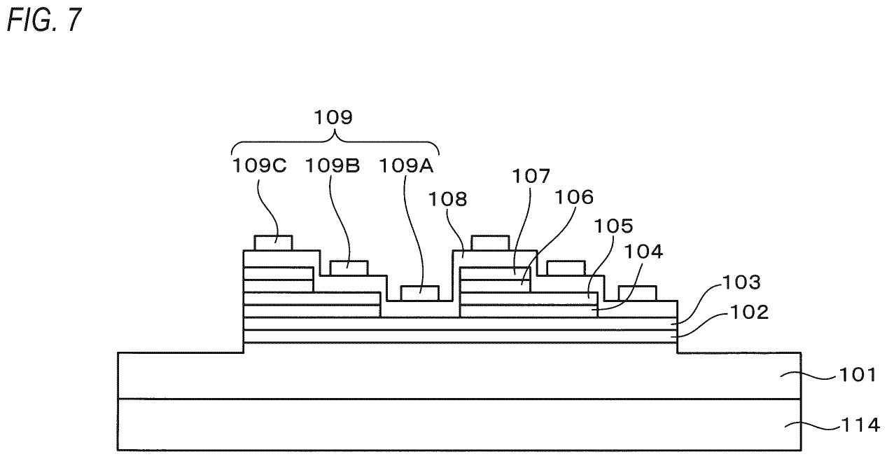

Next, as shown in FIG. 7, by sputtering or vapor deposition, the p-contact electrode 109A is formed on the p-layer 108 in a region of the groove 121, the p-contact electrode 109B is formed on the p-layer 108 in a region of the groove 122, and the p-contact electrode 109C is formed on the p-layer 108 in a region corresponding to an upper portion of the protective layer 107.

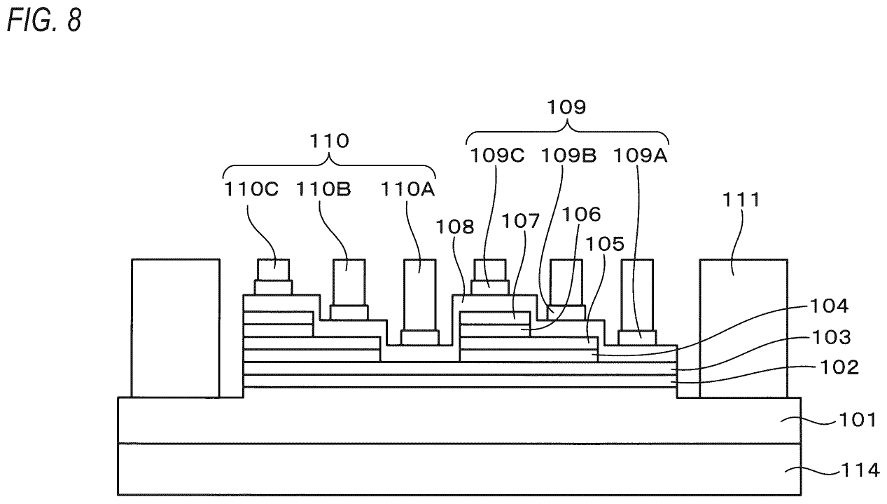

Next, as shown in FIG. 8, by sputtering or vapor deposition, the p-electrodes 110A to 110C are formed on the p-contact electrodes 109A to 109C, and the n-electrode 111 is formed on the n-layer 101 exposed at the bottom surface of the groove 120. Since the p-electrodes 110A to 110C and the n-electrode 111 are made of the same material, the p-electrodes 110A to 110C and the n-electrode 111 can be formed simultaneously.

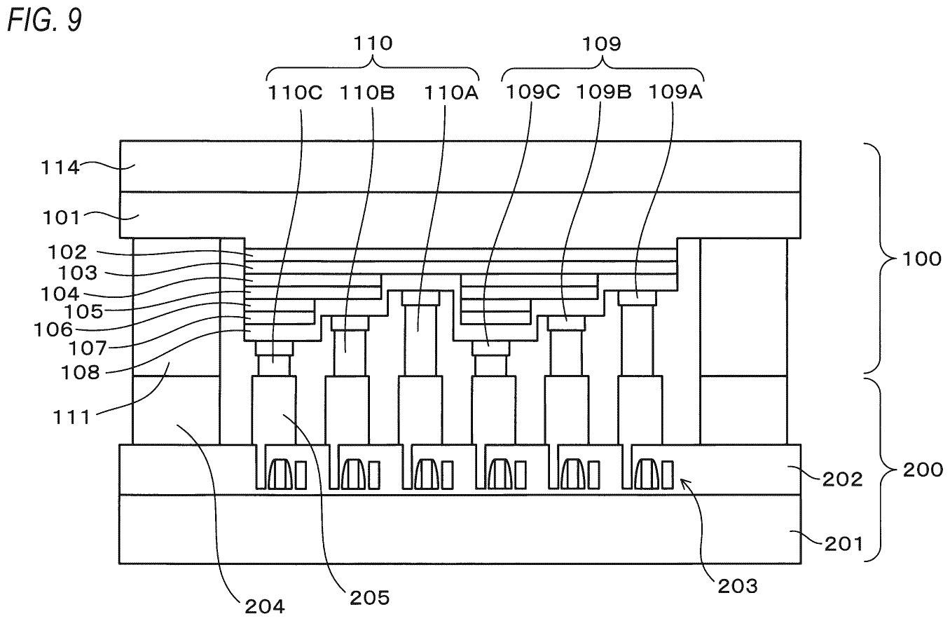

Next, as shown in FIG. 9, the backplane 200 (before the back electrode 206 is formed) is prepared, and the monolithic micro LED 100 are mounted on the backplane 200 by wafer bonding. Thus, the p-electrode 110 of the monolithic micro LED 100 is bonded to the p-side bonding electrode 205 of the backplane 200, and the n-electrode 111 of the monolithic micro LED 100 is bonded to the n-side bonding electrode 204 of the backplane 200.

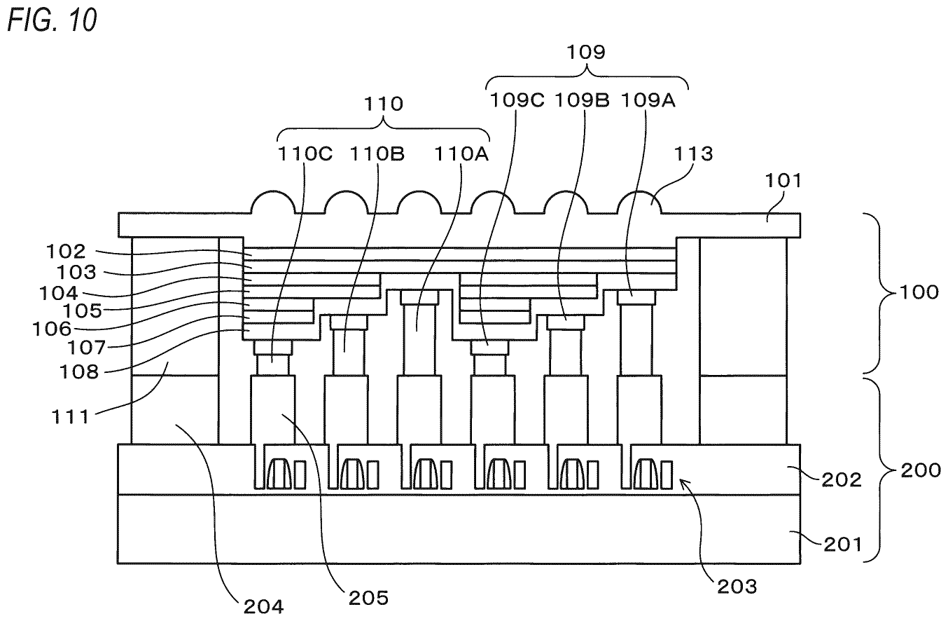

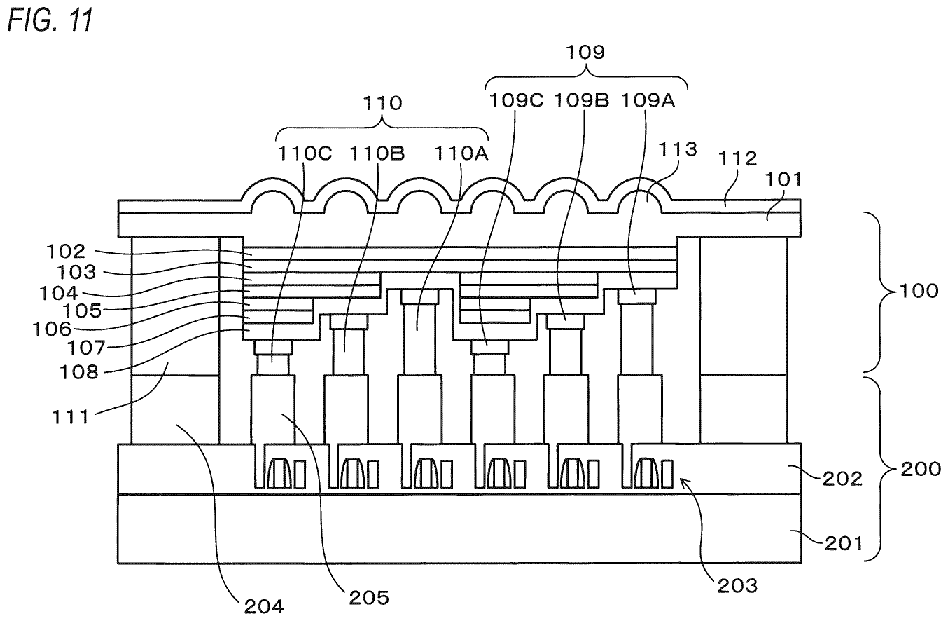

Next, as shown in FIG. 10, the substrate 114 is removed by laser lift-off. Then, the surface of the n-layer 101 exposed by the removal is dry-etched to form the microlens 113. A substrate lift-off method other than laser lift-off, for example, chemical lift-off may be used.

The microlens 113 can be formed, for example, as follows. First, a resist is formed on the n-layer 101 by lithography so as to have a rectangular cross-sectional shape. Then, the cross-sectional shape of the resist is deformed from a rectangular shape to a lens shape by heat treatment, and then the n-layer 101 is dry-etched. Accordingly, the lens shape of the resist can be transferred to the n-layer 101, and the microlens 113 can be formed by processing the n-layer 101 into the lens shape.

Any conventionally known method can be used, such as a method in which a refractive index distribution is generated by ion implantation to form a lens, or a method in which a resist having a lens shape is formed by an ink jet or a gray scale mask, and then dry etched.

Next, the conductive film 112 is formed in a film shape along the unevenness of the microlens 113 on the surface of the n-layer 101. The conductive film 112 is formed by vapor deposition, sputtering, CVD, or the like.

Next, a protective film (not shown) is formed on the conductive film 112. Then, a back surface of the substrate 201 of the backplane 200 is polished and thinned, a hole penetrating the substrate 201 is formed in a predetermined region, a side surface of the groove is covered with an insulating film, and then the back electrode 206 is formed so as to fill the hole. The back electrode 206 is connected to the n-side bonding electrode 204 and the gate and source of the transistor 203 via a circuit including a transistor (not shown) or the like. Next, the monolithic micro LED 100 and the backplane 200 are divided into individual light emitting devices by die working or laser. As described above, since the monolithic micro LED 100 and the backplane 200 are divided into elements after wafer bonding, the outer peripheries of the monolithic micro LED 100 and the backplane 200 coincide with each other in a plan view. Thus, the light emitting device according to the first embodiment can be manufactured.

### 4. Effects of Light Emitting Device According to First Embodiment

According to the light emitting device according to the first embodiment, the conductive film 112 can reduce the substantial sheet resistance of the n-layer 101. Therefore, it is possible to reduce the voltage required for driving the sub-pixel at a position away from the n-electrode 111. In addition, light from each sub-pixel can be narrowed by the microlens 113, and contrast can be improved.

### Second Embodiment

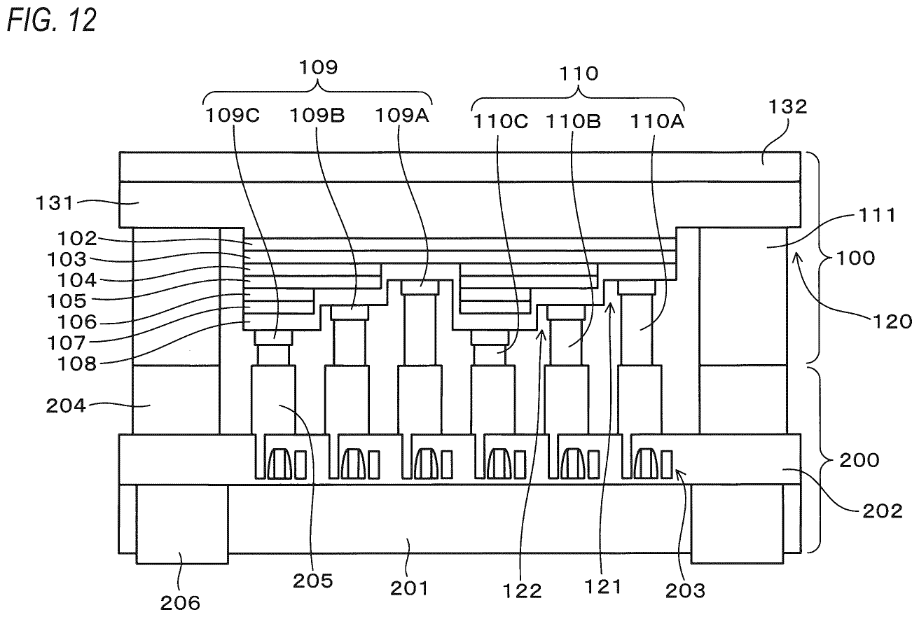

FIG. 12 is a cross-sectional view showing a configuration of a light emitting device according to a second embodiment, and is a cross section perpendicular to a main surface of the light emitting device. The light emitting device according to the second embodiment has the same configuration as that of the first embodiment except that the n-layer 101 and the conductive film 112 of the monolithic micro LED 100 according to the first embodiment are changed to an n-layer 131 and a conductive film 132, respectively.

The n-layer 131 remains flat without providing the microlens 113 on the surface on the light extraction side of the n-layer 101. In addition, the conductive film 132 is the same as the conductive film 112 in the first embodiment except that the conductive film 132 is formed on the surface of the flat n-layer 131.

The light emitting device according to the second embodiment can reduce the substantial sheet resistance of the n-layer 131 as in the light emitting device according to the first embodiment. Therefore, it is possible to reduce the voltage required for driving the sub-pixel at a position away from the n-electrode 111.

### Third Embodiment

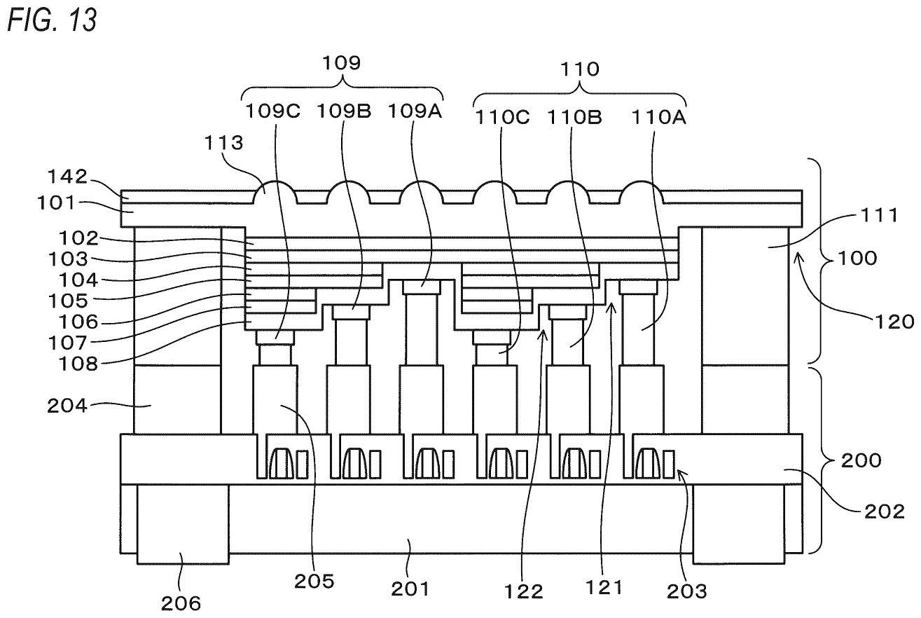

FIG. 13 is a cross-sectional view showing a configuration of a light emitting device according to a third embodiment, and is a cross section perpendicular to a main surface of the light emitting device. The light emitting device according to the third embodiment has the same configuration as that of the first embodiment except that the conductive film 112 of the monolithic micro LED 100 according to the first embodiment is changed to a conductive film 142.

The conductive film 142 is provided in a region of the surface of the n-layer 101 on the light extraction side excluding a region where the microlens 113 is provided. A material of the conductive film 142 may be any conductive material that does not transmit light. For example, conductive carbon nanomaterials such as carbon nanotubes can be used. In this case, the conductive film 142 can be easily formed by coating the n-layer 101 with a solution in which the carbon nanomaterial is dispersed, then precipitating the carbon nanomaterial, and removing the solvent by evaporation or the like.

The light emitting device according to the third embodiment can reduce the voltage required for driving the sub-pixel in a region away from the n-electrode 111, as in the light emitting device according to the first embodiment. In addition, the conductive film 142 can prevent light from passing through a portion other than the microlens 113, and the contrast can be improved.

### Fourth Embodiment

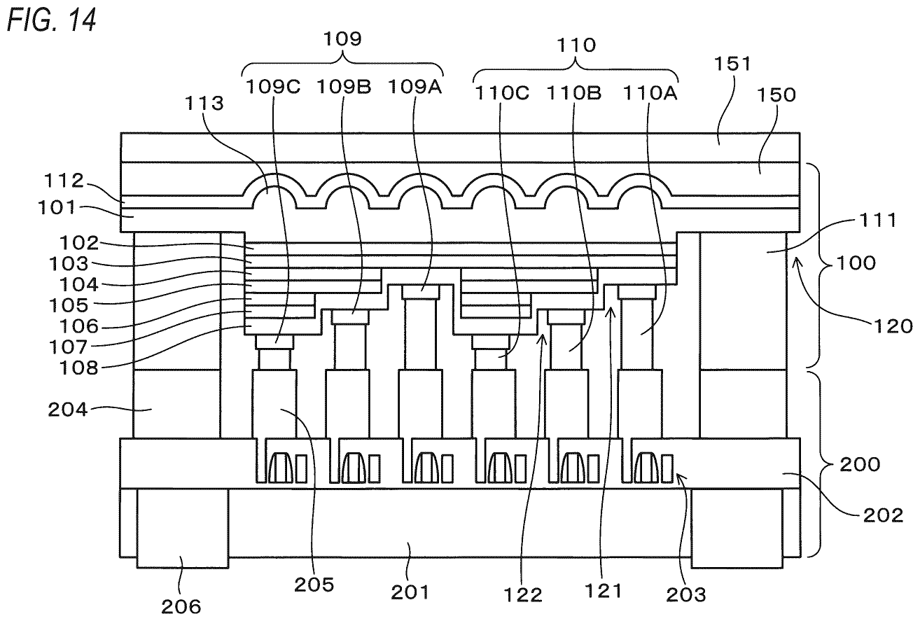

FIG. 14 is a cross-sectional view showing a configuration of a light emitting device according to a fourth embodiment, and is a cross section perpendicular to a main surface of the light emitting device. As shown in FIG. 14, the light emitting device according to the fourth embodiment is obtained by adding a flattening film 150 and a filter 151 to the monolithic micro LED 100 of the light emitting device according to the first embodiment.

The flattening film 150 is provided on a surface of the conductive film 112 opposite to the n-layer 101 side. The flattening film 150 is a film for filling the surface of the n-layer 101 that has become uneven due to the microlens 113 to obtain a flat surface. A material of the flattening film 150 is SiO₂ or the like.

The filter 151 is a dielectric multilayer film provided on a flat surface (a surface opposite to the n-layer 101 side) of the flattening film 150. The dielectric multilayer film is a film in which two types of dielectrics having different refractive indexes are alternately stacked. Since a transmission spectrum of the dielectric multilayer film depends on an incident angle, a variation in the incident angle of light to the dielectric multilayer film is reduced by flattening with the flattening film 150 and providing the dielectric multilayer film on the flat surface.

The number of layers of the dielectric multilayer film and the thickness of each layer of the filter 151 are set so that the transmission spectrum has the following characteristics.

The transmission spectrum of the filter 151 has a transmission band (a band having a transmittance of 90%) in a predetermined range including emission wavelength peaks of the first active layer 102, the second active layer 104, and the third active layer 106. A width of the transmission band is, for example, 20 nm to 50 nm.

Stop bands A and B (bands having a transmittance of 20% or less) are on a short wavelength side of the emission wavelength peak of the third active layer 106 and on a long wavelength side of the emission wavelength peak of the second active layer 104, and on a short wavelength side of the emission wavelength peak of the second active layer 104 and on a long wavelength side of the first active layer 102, respectively. A width of the stop bands A and B is, for example, 10 nm to 40 nm. The stop band A overlaps an emission spectrum of the third active layer 106, and the stop band B overlaps an emission spectrum of the second active layer 104. An upper limit of the stop band A is in a range of λR-30 to λR-10, where λR (nm) is the emission wavelength peak of the third active layer 106. An upper limit of the stop band B is in a range of λG-20 to λG-10, where λG (nm) is the emission wavelength peak of the second active layer 104.

Since the third active layer 106 emits red light, the In composition of the light emitting layer is large, and therefore a variation in In composition is large, resulting in a wide emission spectrum. In particular, spread of the spectrum on the short wavelength side of red causes a decrease in color purity. When the transmission spectrum of the filter 151 is set as described above, the short wavelength side of the emission spectrum of the third active layer 106 can be reduced, and the width of the emission spectrum of the third active layer 106 can be narrowed. Therefore, the color purity of red of the monolithic micro LED 100 can be improved. Similarly, the color purity of green can be increased. As a result, the color gamut of the monolithic micro LED 100 can be widened.

The filter 151 may be directly provided on the conductive film 112 without providing the flattening film 150. However, in this case, since the filter 151 is formed along the shape of the microlens 113, it is necessary to pay attention to the variation in the incident angle to the filter 151.

The fourth embodiment can be similarly applied to the second and third embodiments.

As described above, according to the light emitting device according to the fourth embodiment, the following effects can be obtained in addition to the effects of the light emitting device according to the first embodiment. The filter 151 can increase the purity of red light and green light, and can widen the color gamut of the monolithic micro LED 100.

Next, experimental results according to the fourth embodiment will be described. For a filter of a dielectric multilayer film in which SiO₂ and TiO₂ were alternately stacked, a transmission spectrum was calculated by simulation. The thickness of each layer of the dielectric multilayer film was set so that the transmission spectrum had the transmission bands (band having a transmittance of 90% or more) in the vicinity of a wavelength of 460 nm (in the vicinity of a peak wavelength of blue light of the first active layer 102), in the vicinity of a wavelength of 530 nm (in the vicinity of a peak wavelength of green light of the second active layer 104), and in the vicinity of a wavelength of 620 nm (in the vicinity of a peak wavelength of red light of the third active layer 106), and had the stop bands (band having a transmittance of 20% or less) at wavelengths of 560 nm to 600 nm and 480 nm to 500 nm.

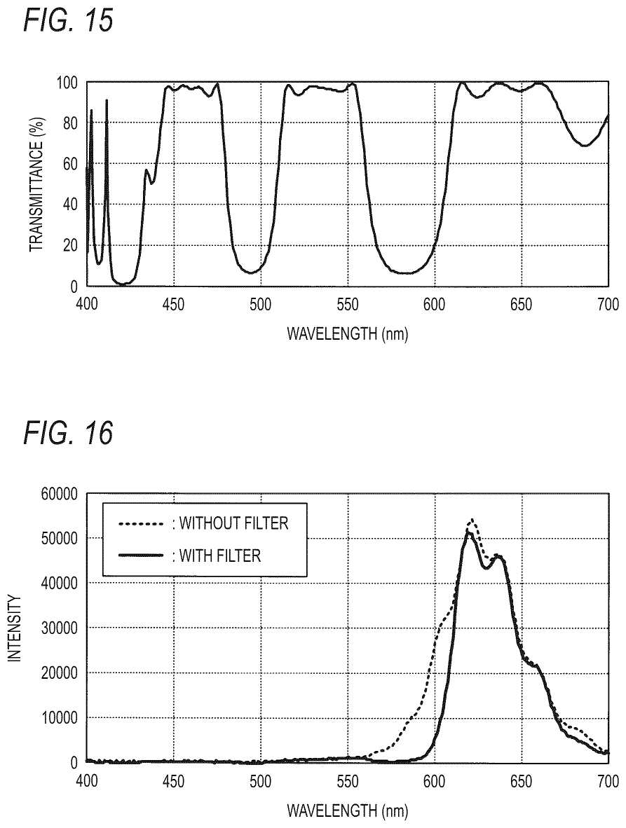

FIG. 15 is a graph showing the transmission spectrum of the filter when the thickness is set as described above. FIG. 16 is a graph showing a result obtained by causing red light emitted from the third active layer 106 to enter a filter having the transmission spectrum of FIG. 15 and determining a spectrum of the transmitted light. FIGS. 15 and 16 show a case of perpendicular incidence. In FIG. 16, a case without a filter shows the spectrum of red light emitted from the third active layer 106, and a case with a filter shows the spectrum of red light transmitted through the filter.

As shown in FIG. 16, it can be seen that the spectrum of the red light emitted from the third active layer 106 is also spread to the short wavelength side, and the purity of the red light is lowered. On the other hand, it can be seen that when the red light is transmitted through the filter, an intensity of the short wavelength side of red light, the wavelength band of 560 nm to 610 nm, is reduced, and a half width of the spectrum is narrowed by about 10 nm. That is, it can be seen that red having high purity is obtained. This is the result that the stop band of the wavelength of 560 nm to 600 nm exists in the filter. Further, although not shown, the green light from the second active layer 104 can be similarly passed through the filter to obtain green light with high purity.

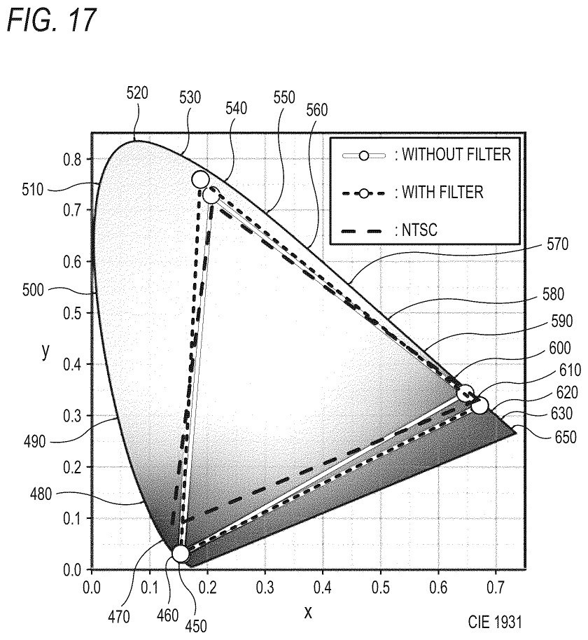

FIG. 17 is a chromaticity diagram showing a range of colors reproducible by the monolithic micro LED 100 according to the fourth embodiment. As shown in FIG. 17, it can be seen that the purity of red and green is increased by the filter, and as a result, the color gamut is also widened.

### Various Modified Embodiments

Although the flip-chip monolithic micro LED 100 is used in the embodiment, the present invention may be applied to other than the monolithic LED, that is, a general LED as long as the present invention is of a flip-chip type.

### REFERENCE SIGNS LIST

100: monolithic micro LED
200: backplane
101, 131: n-layer
102: first active layer
103: first intermediate layer
104: second active layer
105: second intermediate layer
106: third active layer
107: protective layer
108: p-layer
109: p-contact electrode
110: p-electrode
111: n-electrode
112: conductive film
113: microlens

What is claimed is:

1. A flip-chip type light emitting element comprising:
an n-layer made containing a group III nitride semiconductor;
an active layer containing a group III nitride semiconductor provided over the n-layer;
a p-layer containing a group III nitride semiconductor provided over the active layer;
a groove provided at a partial region of the p-layer and having a depth reaching the n-layer;
an n-electrode provided over the n-layer exposed at a bottom surface of the groove;
a p-electrode provided over the p-layer; and
a conductive film provided at a surface of the n-layer opposite to a side in which the active layer is provided and having a region through which light from the active layer is transmitted.

2. The light emitting element according to claim 1, further comprising:
a filter including a dielectric multilayer film over the conductive film, wherein
a transmission spectrum of the filter has a transmission band in a band including λ and a stop band on a shorter wavelength side than λ, where a peak of an emission wavelength of the active layer is λ, and the stop band overlaps with an emission spectrum of the active layer.

3. The light emitting element according to claim 1, wherein
the light emitting element is a monolithic micro LED in which sub-pixels that emit light individually are two-dimensionally arranged.

4. The light emitting element according to claim 2, wherein
the light emitting element is a monolithic micro LED in which sub-pixels that emit light individually are two-dimensionally arranged.

5. The light emitting element according to claim 1, wherein
the conductive film is made from a transparent conductive material.

6. The light emitting element according to claim 2, wherein
the conductive film is made from a transparent conductive material.

7. The light emitting element according to claim 3, further comprising:
a microlens at a position where the microlens faces each of the sub-pixels, at a surface of the n-layer at a side in which the conductive film is provided, wherein
the conductive film is provided, in a region excluding a region at which the microlens is provided, at the surface of the n-layer at the side in which the conductive film is provided, and the conductive film is made from a material that does not transmit light from the active layer.

8. The light emitting element according to claim 4, further comprising:
a microlens at a position where the microlens faces each of the sub-pixels, at a surface of the n-layer at a side in which the conductive film is provided, wherein
the conductive film is provided, in a region excluding a region at which the microlens is provided, at the surface of the n-layer at the side in which the conductive film is provided, and the conductive film is made from a material that does not transmit light from the active layer.

9. The light emitting element according to claim 7, wherein
a total thickness from the n-layer to the p-layer is three times or less a width of each of the sub-pixels.

10. The light emitting element according to claim 8, wherein
a total thickness from the n-layer to the p-layer is three times or less a width of each of the sub-pixels.

11. The light emitting element according to claim 7, wherein
a total film thickness from the n-layer to the p-layer is twice or less a width of each of the sub-pixels.

12. The light emitting element according to claim 8, wherein
a total film thickness from the n-layer to the p-layer is twice or less a width of each of the sub-pixels.

13. A light emitting device comprising:
the light emitting element according to claim 3; and
a backplane connected to the n-electrode and the p-electrode of the light emitting element and including a drive circuit that individually drives the sub-pixels of the light emitting element.

14. The light emitting device according to claim 13, wherein
the backplane is provided with s a back electrode connected to the drive circuit at a surface of the backplane at a side opposite to a side in which the light emitting element is provided.

15. The light emitting device according to claim 13, wherein
an outer periphery of the light emitting element and an outer periphery of the backplane coincide with each other in a plan view.
